(19) United States
(12) Patent Application Publication
(10) Pub. No.: US 2015/0179418 A1
(43) Pub. Date: Jun. 25, 2015

(54) MINIATURE PHYSICAL VAPOUR DEPOSITION STATION

(71) Applicant: Milman Thin Film Systems Pvt. Ltd., Pune, MH (IN)

(72) Inventors: Mandar Ashtikar, Pune (IN); Milind Acharya, Pune (IN)

(21) Appl. No.: 14/414,705

(22) PCT Filed: Aug. 7, 2013
(86) PCT No.: PCT/IB2013/056455

§ 371 Date: Jan. 16, 2015

(30) Foreign Application Priority Data
Aug. 8, 2012 (IN) 363/MUM/2012

(51) Int. Cl. H01J 37/34

(52) U.S. Cl. CPC H01J 37/3488; H01J 37/3405; H01J 2237/32

(57) ABSTRACT

The present invention is directed towards a physical vapor deposition station rendered novel in its miniature scale of operations and interchangeability of components to achieve amongst a plurality of vapor deposition methodologies and and surface treatment techniques available. Also disclosed is its distributed control and management using specific combination of instructional content integrated into a base station and removable flash drives at disposal of the operator.

### CROSS-REFERENCE TO RELATED APPLICATIONS

This application is filed as a national phase application under 35 U.S.C. §371 further to international application No. PCT/IB2013/056455 and claims priority from Indian application for patent No. IN363/MUM/2012 filed on Aug. 8, 2012.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### FIELD OF THE INVENTION

The present invention relates generally to equipment for realization of physical vapor deposition of thin films by the condensation of a vaporized form of the desired film material onto various substrates and more particularly to construction, assembly and operation of a compact device in which various Physical Vapor Deposition (hereinafter referred to as “PVD”) coating processes can be managed on a bench scale/in a table top system.

The present invention further relates to enablement of various PVD and plasma treatment/surface modification processes in said compact device.

### BACKGROUND OF THE INVENTION

A number of disciplines have been developed over the years in the physical vapor deposition art for applying or depositing a coating layer on a substrate surface within a vapor deposition chamber. Certain fundamental process steps are the same for all of the vapor deposition disciplines, although a large number of variations and techniques in implementing the process steps have been developed. Generally, the substrate to be coated is placed within a deposition chamber, which is typically evacuated and depending on the process a controlled atmosphere of certain gas is created inside deposition chamber. The coating material to be deposited on the substrate is generated within or introduced into the chamber, and assumes the form of a plasma that includes gaseous vapors and solid particulate matter. The plasma may include atoms, molecules, ions, and agglomerates of molecules of the coating material, as well as those of any desired reactant agents and any undesired impurities. The coating or deposition process itself occurs by condensation of the plasma coating particles onto the substrate surface(s) to be coated.

Vapor deposition processes are generally categorized into “chemical” and “physical” vapor deposition disciplines. Both generally incorporate a deposition or coating chamber in which a “plasma” is used to produce the coating material which is transported toward a substrate to be coated. The uses of the coatings applied to substrates, and the shapes and materials of the substrates can vary widely, from decorative coatings on ceramic or pottery materials, to circuit interconnection wiring paths on the surfaces of semi-conductor chips, to wear-resistant coatings on cutting tool and functional application on bearing surfaces. Similarly, the physical nature and properties of the coating materials vary widely, from conductive coatings, to semiconductive coatings, to those forming electrical insulators.

Physical Vapor Deposition (PVD) is a broad term for deposition techniques that utilize the physically vaporized form of a desired coating material to create a deposited film on a substrate. Techniques include those that facilitate a physical (rather than chemical) vaporization of the base material, such as electron beam evaporation, thermal evaporation, point source evaporation, and magnetron sputtering.

Physical vapor deposition processes generally require prior evacuation of the deposition chamber, and maintenance of a negative pressure level during, the deposition process. Coating material to be deposited is generally present in the deposition chamber in non-gaseous form. The typically solid sacrificial source material is acted upon by an energy stimulus by plasma that converts the solid source material into a vaporous coating material. Once converted into a vapor/plasma, a coating source material may be combined with reactive gases or other elements within the chamber to form coating compounds and molecules prior to actual deposition thereof onto substrate(s). The coating plasma typically includes atoms, molecules, ions, ionized molecules, and agglomerates of molecules. The deposition process can be enhanced by creating ionic attraction between the plasma particles and the substrate surface(s) by applying negative bias voltage to the substrate surface(s).

There are a number of different physical vapor deposition techniques, which are distinguished by the manner in which the source material is vaporized. The most commonly used physical vapor deposition techniques for converting the solid coating source material into a gaseous/vapor plasma are: (a) resistance or induction heating; (2) electron beam or ion bombardment; (3) electric arc; and (4) plasma.

Generally, known PVD coating devices, for example such as magnetron sputtering devices or arc evaporation devices are used to provide a plurality of tools, components and ornaments with suitable coatings in order to give their surfaces value-added functional and/or possibly also decorative configurations. Thermal deposition, magnetron sputtering deposition, plasma enhanced physical vapor deposition, arc deposition and electron beam deposition are conventionally used methodologies for achieving said coatings. Numerous devices generally specific to either of these coating methodologies and end application(s) intended are known in the art. However, said devices are unanimously bulky, expensive to procure and operate.

From prior art studies undertaken, there appear some attempts at achieving construction of small scale PVD coaters. However, these suffer from numerous limitations, first in range of deposition materials supported—gold or platinum films only; second, application reserved to carbon evaporation and sample preparation for electron microscopy; and third, number of technologies made available in the same equipment set.

From brief study of the art, it may be appreciated that existing solutions have not been fully effective in addressing the need of the art. Thus, a compact PVD coater device capable of providing functionalities of large scale coaters at low construction and operation costs along with incorporation of numerous state of the art PVD and plasma processes with/without modifications is a pressing need of the art.

The present inventors, in cognizance of aforesaid needs and technical problems, have undertaken focused research and come up with novel solution to address the same. The following description presents one way of performing the present invention.

### OBJECTS OF THE PRESENT INVENTION

The principle object of the present invention is to provide for deposition device for forming a film by physical vapor deposition at much reduced scale of operations than available hitherto.

Yet another object of the present invention is to provide a physical vapor deposition system characterized in being able to integrate various methods of physical vapor deposition without requirement of substitution of entire system.

Yet another object of the present invention is to provide a physical vapor deposition system characterized in providing for multiplicity of various methods of physical vapor deposition.

Yet another object of the present invention is to provide a physical vapor deposition system characterized in having costs-effective selection of materials, assemblage and operations

It would be convenient hereinafter to describe the present invention in greater detail by reference to the accompanying drawings which illustrate preferred embodiments of the invention. The drawings are not necessarily to scale, emphasis instead being placed upon illustrating the principles of the present invention.

### BRIEF DESCRIPTION OF DRAWINGS

Table 1 is an comparative account of dimensions/parameters of the miniature PVD Station proposed herein to a conventional thermal evaporation system

FIGS. 1(a), 1(b) and 1(c) are schematic illustrations of the front, perspective and plan views of one embodiment of the physical vapor deposition station having circular chamber

FIGS. 2(a), 2(b) and 2(c) are schematic illustrations of the front, perspective and plan views of one embodiment of the physical vapor deposition station having rectangular chamber.

FIGS. 3(a) and 3(b) are schematic illustrations of the front cross-section and isometric views of blank chamber of the physical vapor deposition station proposed herein in its circular configuration

FIGS. 3(c) and 3(d) are schematic illustrations of the front and isometric views of blank chamber of the physical vapor deposition station proposed herein in its rectangular configuration

FIGS. 4(a) and 4(b) are schematic illustrations of the front and isometric views of circular chamber of the physical vapor deposition station proposed herein in its magnetron sputtering configuration

FIGS. 4(c) and 4(d) are schematic illustrations of the front and isometric views of rectangular chamber of the physical vapor deposition station proposed herein in its magnetron sputtering configuration

FIGS. 5(a), 5(b) are schematic illustrations of the front and isometric views of circular chamber of the physical vapor deposition station proposed herein in its thermal evaporation configuration

FIGS. 5(c) and 5(d) are schematic illustrations of the front and isometric views of rectangular chamber of the physical vapor deposition station proposed herein in its thermal evaporation configuration

FIGS. 6(a), 6(b) are schematic illustrations of the front and isometric views of circular chamber of the physical vapor deposition station proposed herein in its plasma treatment configuration

FIGS. 6(c) and 6(d) are schematic illustrations of the front and isometric views of rectangular chamber of the physical vapor deposition station proposed herein in its plasma treatment configuration

FIGS. 7(a), 7(b) and 7(c) are schematic illustrations of the front, front section and isometric section views of another embodiment of the physical vapor deposition station in its dual magnetron sputtering configuration.

FIG. 8(a) is a block diagram illustrating the process flow of the physical vapor deposition station in its magnetron sputtering configuration

FIG. 8(b) is a block diagram illustrating the process flow of the physical vapor deposition station in its thermal evaporation configuration

FIG. 8(c) is a block diagram illustrating the process flow of the physical vapor deposition station in its plasma treatment configuration

A better understanding of the objects, advantages, features, properties and relationships of the present invention will be obtained from the following narration which is indicative of the various ways in which the principles of the invention may be employed.

### SUMMARY OF THE PRESENT INVENTION

The present invention is directed towards a physical vapor deposition station rendered novel, in one aspect, in its miniature scale of operations, and, in another aspect, by interchangeability of components to achieve amongst a plurality of surface treatment techniques available. A preferred embodiment of the miniature physical vapor deposition station of this invention includes a base station onto which three subsystems may be selectively mounted to enable either among plasma, magnetron and thermal deposition methods. Alternative embodiments of the present invention disclose different chamber geometries and multiplicity of coating functionality that may be simultaneously organized using assembly indicated hereinafter. Distributed yet interdependent control and management of each of these subsystems and their variant is achieved via specific combination of instructional content integrated into the base station and removable flash drive(s) that the user may select according to end application(s) intended.

Construction, positioning, actuation and operation of this system are few novel areas described in the drawings and detailed description to follow.

### DETAILED DESCRIPTION OF THE INVENTION

In view of the foregoing disadvantages inherent in the known systems now present in the prior art, the present invention provides a compact miniature bench-scale/table top physical vapor deposition station which incorporates all advantages of the prior art but none of its disadvantages.

In this respect, before explaining at least one embodiment of the invention in detail, it is to be understood that the invention is not limited in its application to the details of construction and to the arrangements of the components set forth in the following brief description. The invention is capable of other embodiments and of being practiced and carried out in various ways. Also, it is to be understood that the phraseology and terminology employed herein are for the purpose of description and should not be regarded as limiting. Hereinafter, subject to context presented, terminologies shall have their usual meanings and similar numerals shall denote same component being indexed

As known from teachings of the art, Physical Vapor Deposition (PVD) is a variety of vacuum deposition methods used to deposit thin films by the condensation of a vaporized form of the desired film material onto various workpiece surfaces. The coating methods involve purely physical processes for creation of vapors such as high-temperature vacuum evaporation with subsequent condensation, or plasma sputter bombardment rather than involving a chemical reaction at the surface to be coated as in chemical vapor deposition.

The prior art recognizes the desirability in certain instances of physical vapor deposition apparatuses capable of forming smooth, homogeneous films on the substrate and are additionally made adaptable to receive preferably more than one among plasma, magnetron and thermal deposition methods without requiring large increments in costs, tooling or infrastructure. The prior art, to the extent accessed, lacks any precedent to construction and operation of a PVD station on a bench scale/as a table top model. The present inventors address these and other needs in the manner outlined in the description to follow. Table 1 is a comparative account of dimensions/parameters of the miniature PVD Station proposed herein to a conventional thermal evaporation system. It shall be understood that functionality of the latter is restricted to a single process of thermal evaporation while the former additionally provides for processes such as plasma treatment and magnetron sputtering. Scale down is not thus the only aspect of consideration in these presents.

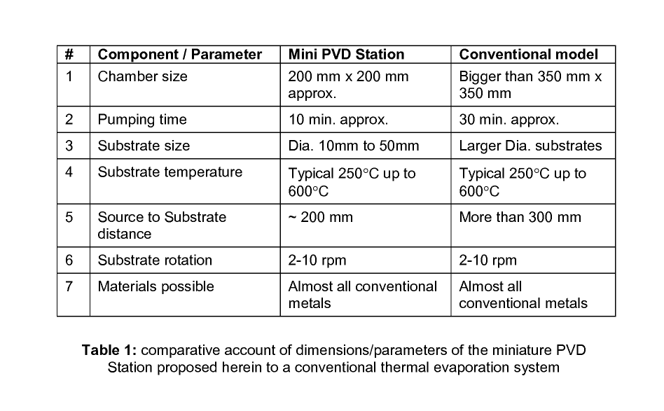

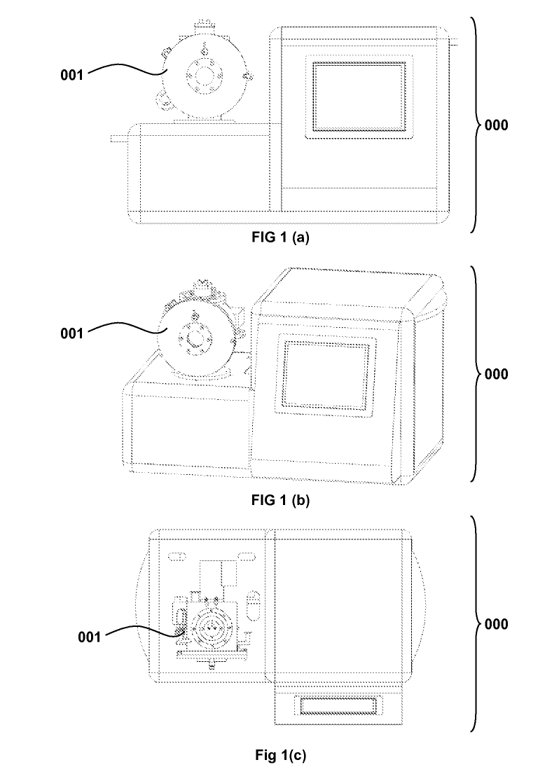

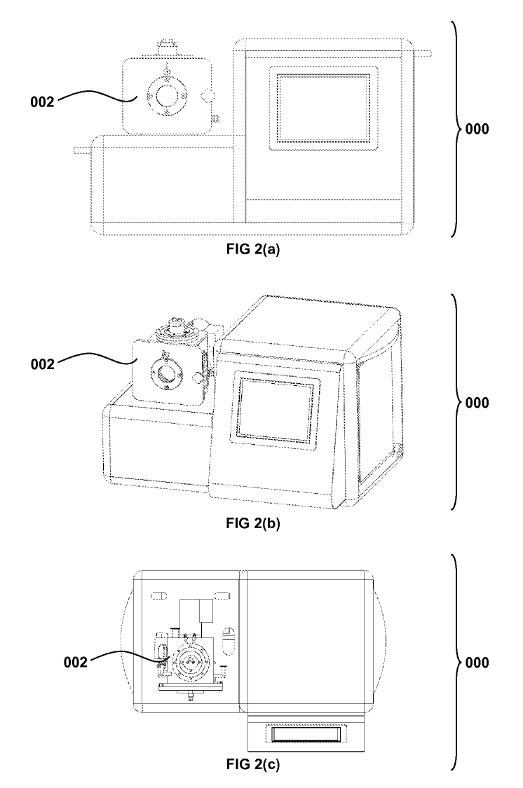

Constructional features of a PVD coater device are hereby recited in accordance with principles of the present invention which constitute a non limiting example. According to one embodiment of the present invention illustrated in FIGS. 1(a to c) and FIGS. 2(a to c), it can be seen that the PVD coater device is a table top model 000 with a small SS 316/SS304/55304L process chamber of dimensions φ 200 mm×200 mm height which are miniature compared to chambers conventionally provided for in the art. The present invention derives its novelty, in one aspect, from the arrangement of operations on a bench/table-top scale than large scales available previously. The process chamber, in alternative embodiments, is made of a cylindrical geometry 001 or rectangular geometry 002.

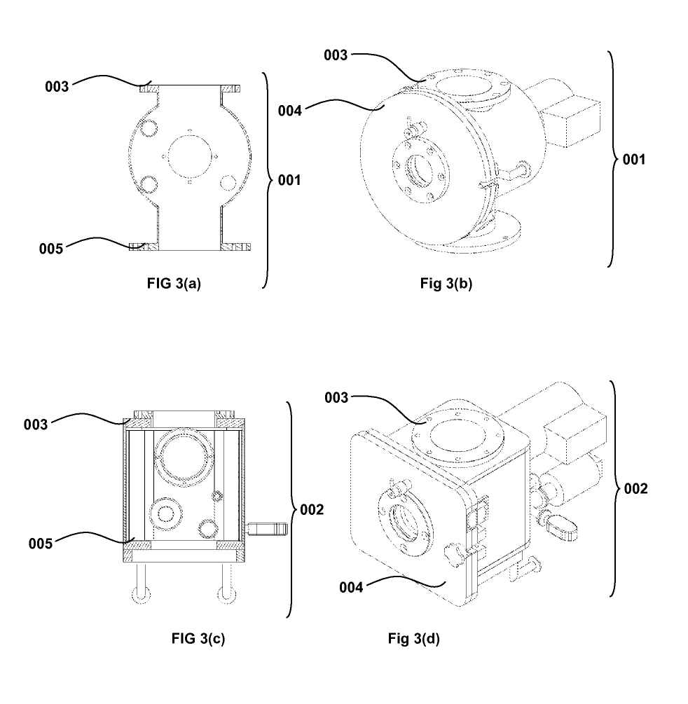

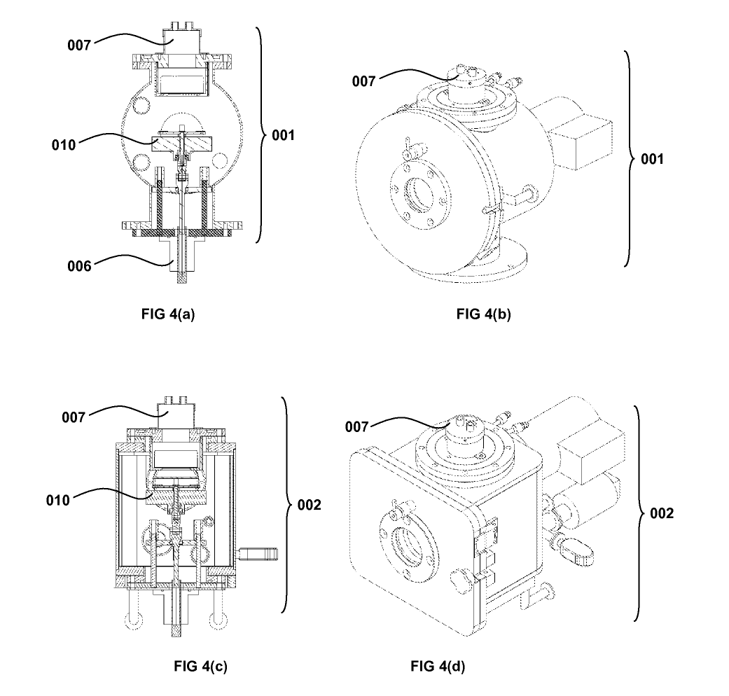

FIGS. 3(a) and 3(b) are schematic illustrations of the front cross-section and isometric views of blank chamber of the physical vapor deposition station proposed herein in its circular configuration. FIGS. 3(c) and 3(d) are schematic illustrations of the front and isometric views of blank chamber of the physical vapor deposition station proposed herein in its rectangular configuration. Here, differences between cylindrical geometry 001 or rectangular geometry 002 are for aesthetic reasons as well as technical requirements of the end application intended. Internal and surface construction otherwise bear identity with each other. Flanges 003, 004 and 005 on top, front and bottom of the chamber help docking of interchangeable components, serving as material loading portal bearing observation window and docking to base station 000 respectively. Flange 004 also helps docking of said interchangeable components. Suitable seals are used for docking of aforementioned flanges to achieve ideal chamber environment for PVD processes to be performed. Wilson seal assembly 006 (shown in FIG. 4a) is used for integration of the rotary driver (not shown in drawings) to substrate table 010.

According to another aspect of the present invention, the chambers 001 or 002 are evacuated by means of small turbo molecular pump (not shown in drawings) which ensures clean and fast vacuum.

According to another aspect of the present invention, the said PVD station of the present invention can be enabled to perform various operations in addition to and in lieu of magnetron sputtering deposition, thermal evaporation, plasma enhanced chemical vapor deposition, reactive ion etching, plasma asher, plasma surface treatment and electron beam evaporation by making appropriate additions/changes in top and bottom flanges of the process chamber. Irrespective of said modifications, the performance of equipment and properties of the coatings remains unaffected. Reference is now had to following non-limiting examples which showcase different operational configurations that may be had with the physical vapor deposition of the present invention.

### EXAMPLE 1

### Magnetron Sputtering Configuration

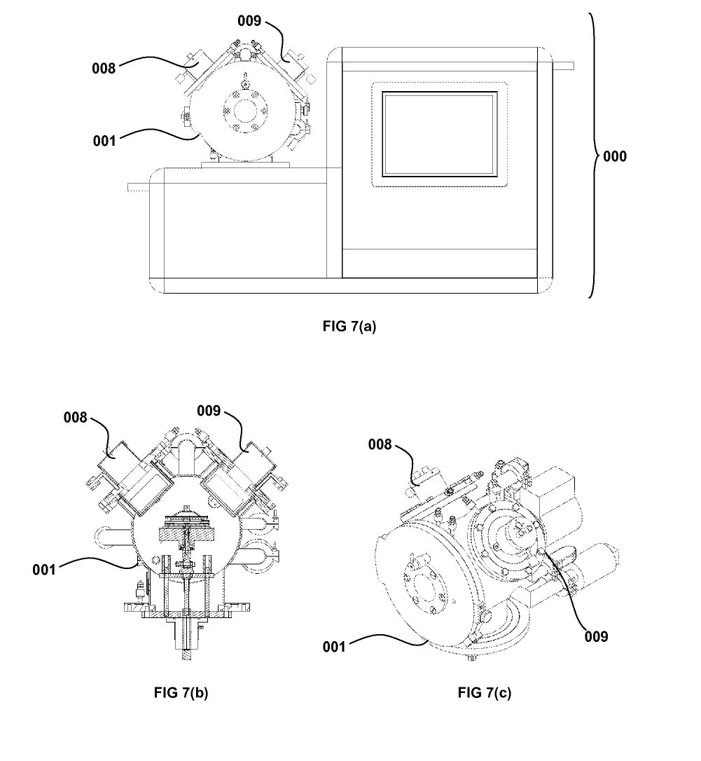

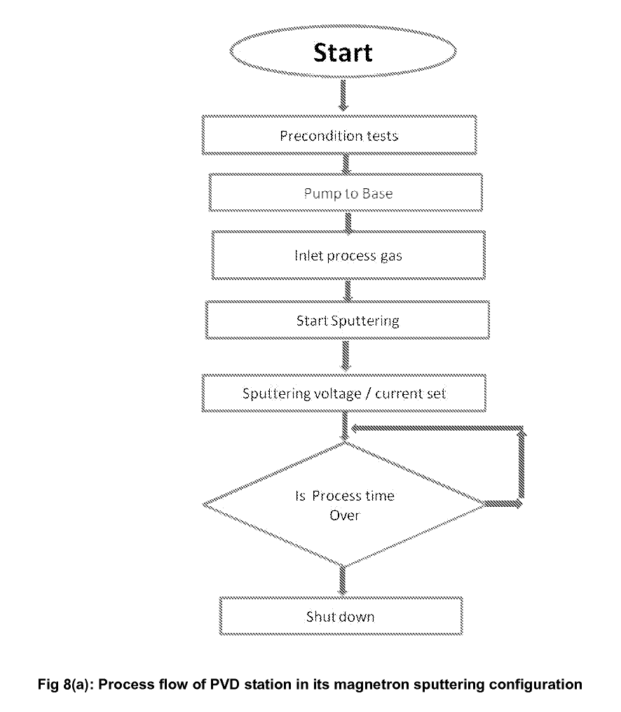

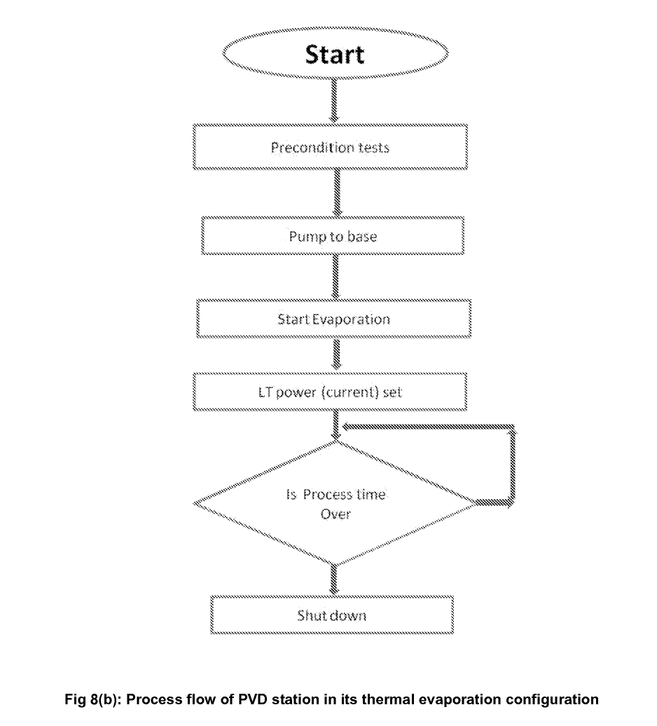

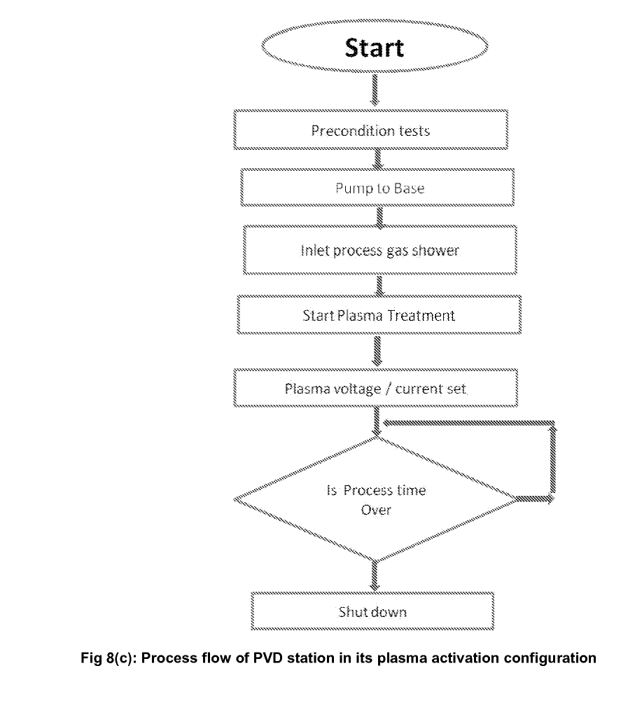

Referring to FIGS. 4(a to d) which shows assembly of the chamber 001 or 002 in magnetron sputtering configuration, the chamber 001 or 002 contains a magnetron assembly 007 comprising a cathode of diameter 2″ or 3″ size i.e. the target size is 2″ to 3″ and includes DC, Pulsed DC or RF power supply as per the end application intended. In an alternate embodiment and specifically referring to FIGS. 7(a to c), the station 000 of the present invention can be also offered with two magnetron cathodes 008 and 009 as well as with digital thickness monitor (not shown in drawings) as an option. This two cathode embodiment is essentially in confocal geometry. Process flow for this typical magnetron sputtering configuration is elaborated in FIG. 8. Referring back to FIGS. 4(a to d), it may be seen that substrate table 010 has a facility of rotation as well as tilting arrangement continuously through different angle from 0 to 45°. Large substrate table size can be also provided as per requirement which can be used in the absence of thickness monitor.

### EXAMPLE 2

### Thermal Evaporation Configuration

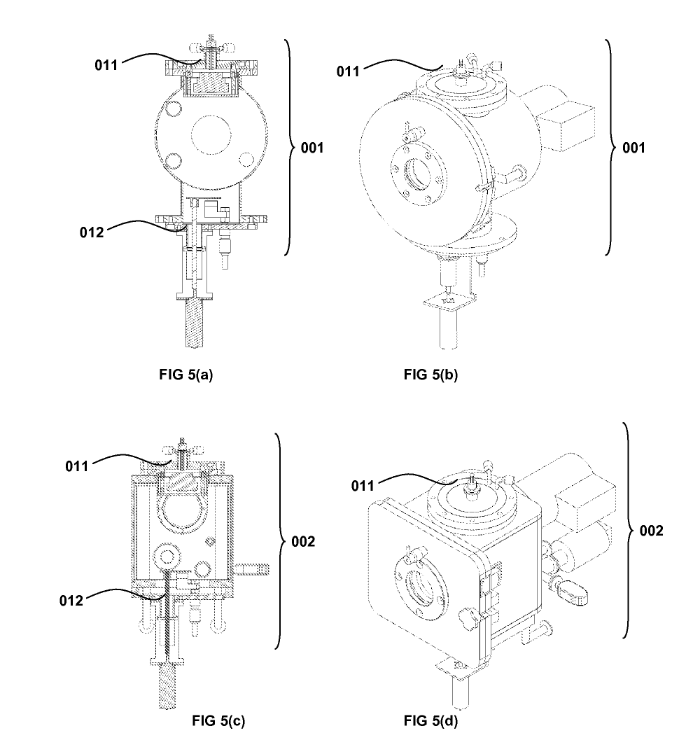

FIGS. 5(a), 5(b) and 5(c), 5(d) are schematic illustrations of the front and isometric views of alternative circular or rectangular chamber respectively of the physical vapor deposition station proposed herein in its thermal evaporation configuration. 011 and 012 indicate the substrate with the heater assembly and thermal source assembly which engage at the flanges 003 and 005 respectively. Process flow for this configuration is elaborated in FIG. 8(b).

### EXAMPLE 3

### Plasma Treatment Configuration

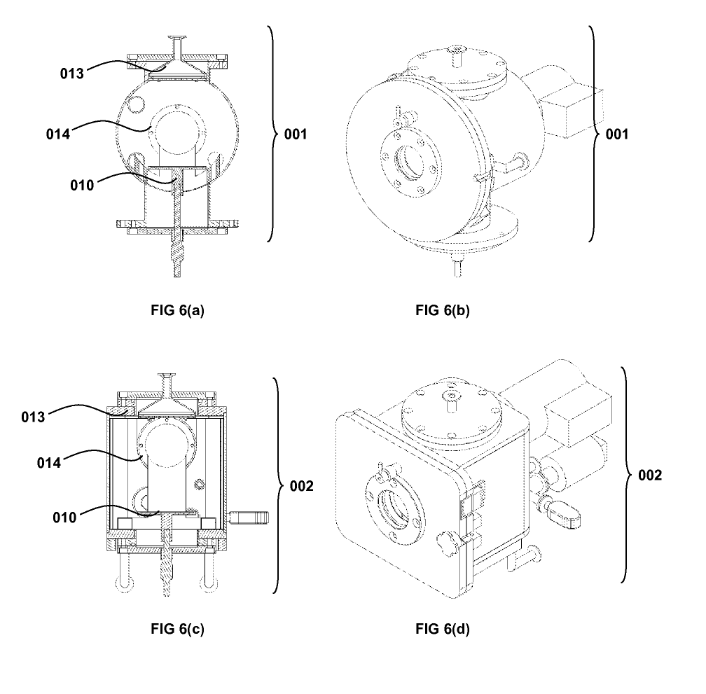

FIGS. 6(a), 6(b) are schematic illustrations of the front and isometric views of circular chamber of the physical vapor deposition station proposed herein in its plasma treatment configuration. 010, 013 and 014 indicate the substrate table, shower assembly and pumping scheme respectively. Process flow for this configuration is elaborated in FIG. 8(c).

According to another inventive feature of the present invention, the overall selection and performance among various operational modes is controlled via synergistic content data bifurcated for storage in the PVD station 000 and a flash drive (not shown in drawings). Accordingly, master control routine is present in the station 000 while job-specific process parameters/loops/data may be incorporated in the flash drive the combination of which defines the process and output of the PVD station proposed herein. It shall be amply evident to the reader that relational content stored in the PVD station 000 and a flash drive shall include but not be limited to process flows illustrated in FIGS. 8(a to c). It is to be also understood that common networking and data communications processes and principles are contemplated herein as being applicable to communications between devices, modules and components in this invention. These aspects are intended to be covered in further embodiments of the present invention.

According to another aspect of the present invention, interchange between operative configurations is not subject to intensive tooling or time requirements. For example, steps for transforming the PVD station 000 from one configuration, say magnetron sputtering, to another configuration, say thermal evaporation, involves following steps:
a) Removing top flange 003 carrying Magnetron Sputtering Cathode by unfastening its (eight) screws.
b) Substituting another flange in place of flange 003 with substrate holder designed for thermal evaporation in its place and fastening with (eight) screws.
c) Making external power connections to the heater provided with substrate holder to the heater power supply located inside equipment panel.
d) Fixing suitable size and type of substrate on the substrate holder with the help of given clamps.
e) Removing bottom flange 005 with substrate holder designed for sputtering process by unfastening (eight) screws.
f) Substituting another flange in place of flange 005 carrying thermal evaporation source assembly in its place by fastening (eight) screws.
g) Connecting thermal evaporation source assembly to the LT power supply provided separately with the help of given copper braided wires.
h) Fixing suitable evaporation boat/filament on the source and fill with desired material to be deposited.
i) Substituting flash drive programmed for sputtering process from the station 000 with flash drive programmed for thermal evaporation process
j) Connecting mains power to the equipment and performing operation intended.

It is advantageous feature of the present invention that installation and commissioning of said PVD coater device does not require an elaborate setup in terms of utilities and space. The said PVD coater device consumes low power and a small water chiller can take care of all the cooling requirements. The said PVD coater device can be operated through touch screen HMI located on the front panel. The operation can be in Manual or Auto mode.

### INDUSTRIAL APPLICABILITY

The systems and methods of this invention provide numerous advantages and benefits:
a) Production of thin films of metals and dielectrics
b) Achievement of co-sputtered films, alloy films and multilayers in a single operation
c) Ability to deposit films by thermal evaporation in a shortest cycle times
d) Ability to achieve reactive magnetron sputter deposition of films
e) Deposition of all metallic films including gold, gold/palladium and platinum on silicon wafer, glass, metal ceramic substrates for various end uses including but not limited to:
   1) Decorative and jewelry applications
   2) Contacts for small photovoltaic devices
   3) Sensors and devices in general
   4) Smart materials/Nanotechnology
   5) Metal patterns for various applications
   6) Plasma based surface treatments for medical applications

Using the miniature PVD station of the present invention, uniform sputter deposition or any other process is possible on substrates of size 1″×1″ square or φ 1″ circular substrates. Types of substrate that can be used include silicon wafer, glass, metal, ceramic and so on.

As will be realized, the present invention is capable of various other embodiments and that its several components and related details are capable of various alterations, all without departing from the basic concept of the present invention. Therefore, the invention should not be regarded as being limited in scope to the specific embodiments of method and system or operations disclosed herein, but instead as being fully commensurate in scope with the following claims.

We claim:

1. A miniature physical vapor deposition station capable of being configured for performing various vapor deposition, plasma treatment and surface modification processes, said station comprising:
a base station to house the means providing mechanical, electrical, control, material inputs and connectivity necessary for performing the process intended;
a hollow stainless steel chamber admeasuring 200 mm×200 mm operably attached to the base station 000 via a first sealable coupling means at its flange 005 to define an enclosed cavity within which the substrate to be processed is hosted on table 010 having ability to rotate and tilt through 0° to 45° angles; and
a library of interchangeable components capable of being attached via sealable coupling means to the hollow chamber and base station at sites marked by flanges 003 and 005 respectively to arrive at configurations chosen among magnetron sputtering, thermal evaporation, plasma treatment, their variants and combinations; and
distributed interactive means for control and management of the processes performed by the miniature physical vapor deposition station.

2. The miniature physical vapor deposition station according to claim 1, wherein said means providing mechanical, electrical, control and material inputs comprise at least one each among a drive motor, vacuum pump, cooling system, power supply, vacuum gauge, user interface and piping suitable for conveying fluids and gases used.

3. The miniature physical vapor deposition station according to claim 1, wherein the distributed control and management of the processes performed by the miniature physical vapor deposition station is achieved by interaction between contextual data stored on an electronic storage on-board the base station 000 and a removable flash drive connectable to base station 000.

4. The miniature physical vapor deposition station according to claim 3, wherein said contextual data comprises definition of operational parameters, their tolerance limits, optimized values and logic presented in process flows of FIGS. 8(a), 8(b) and 8(c) of which the electronic storage on-board the base station 000 preferably receives the generic content and the removable flash drive preferably receives content specific to process-application intended.

5. The miniature physical vapor deposition station according to claim 2, wherein said user interface is an electronic display panel bearing controls and switches selected among push button and capacitive touch screen varieties the actuation of which by the human operator, after plugging in of the flash drive containing contextual data specific to process-application intended, enables intended operation of the miniature physical vapor deposition station.

6. The miniature physical vapor deposition station according to claim 1, wherein said library of interchangeable components comprises preferably one each among a magnetron cathode assembly attached via sealable coupling means to the hollow chamber at site marked by flange 003, substrate stage 010 at site marked by flange 005 and a flash drive bearing contextual data for performance of magnetron sputtering process.

7. The miniature physical vapor deposition station according to claim 1, wherein said library of interchangeable components comprises preferably one each among a substrate stage 010 with heater assembly attached via sealable coupling means to the hollow chamber at site marked by flange 003, a thermal source assembly adjoined to the hollow chamber at site of coupling marked by flange 005 to base station and a flash drive bearing contextual data for performance of thermal evaporation process.

8. The miniature physical vapor deposition station according to claim 1, wherein said library of interchangeable components comprises preferably one each among a gas shower assembly attached via sealable coupling means to the hollow chamber at site marked by flange 003, substrate stage 010 at site marked by flange 005, evacuation assembly attached directly to the hollow chamber and a flash drive bearing contextual data for performance of plasma treatment process.

9. The miniature physical vapor deposition station according to claim 1, wherein said sealable coupling means for attaching the base station to hollow chamber, interchangeable components to the hollow chamber and closing observation window of the hollow chamber are mated flanges on each of their docking surfaces that optionally enclose sealing O-rings and bear, along their circumferences, fasteners including screws, nut-bolts, and clamps.

10. The miniature physical vapor deposition station according to claim 1, the thermal evaporation configuration of which is characterized in having:
a pumping time of 10 minutes;
capability to process a substrate size ranging from 10 mm to 50 mm;
capability to attain substrate temperatures ranging from 250° C. up to 600° C.;
a source to substrate distance of around 200 m; and
substrate rotation of 2-10 rpm.

11. The miniature physical vapor deposition station according to claim 1, said station 000 optionally capable of configurations comprising a plurality of the assemblies required for magnetron sputtering, plasma treatment and thermal evaporation processes.

12. The miniature physical vapor deposition station according to claim 1, wherein said chamber is optionally made to circular or rectangular geometries depending on requirements of processes intended, aesthetics and resource costs.
